(19) United States
(12) Patent Application Publication
(10) Pub. No.: US 2009/0122830 A1
(43) Pub. Date: May 14, 2009

(54) SURFACE ACOUSTIC WAVE TRANSPONDERS

(75) Inventor: Michel CHOMIKI, Cagnes Sur Mer (FR)

Correspondence Address: LOWE HAUPTMAN & BERNER, LLP, 1700 DIAGONAL ROAD, SUITE 300, ALEXANDRIA, VA, 22314, US

(73) Assignee: SENSEOR, Sophia Antipolis (FR)

(21) Appl. No.: 11/721,955

(22) PCT Filed: Dec. 14, 2005
(86) PCT No.: PCT/EP2005/056779

§ 371 Date: Jun. 15, 2007

(30) Foreign Application Priority Data
Dec. 15, 2004 (FR) 0413336

(51) Int. Cl. G01K 7/32; H01L 41/107

(52) U.S. Cl. 374/119; 310/313 D

(57) ABSTRACT

The field of the invention is that of surface acoustic wave transponders and associated devices. This invention applies more particularly to the techniques for identifying and locating transponders. It also applies to the transmission of information or measurements, the transponder then being used as a transducer. This type of transponder can, in particular, be used on vehicles, and in particular on road vehicles. The inventive transponder (1) comprises a surface acoustic wave device, comprising one or more electronic filters (101) with narrow spectral band centered on one or more central frequencies and a delay line (102) operating in reflection mode. By having narrowband filters centered on different frequencies, it is thus possible to easily discriminate between different transponders. The delay lines make it possible to simply separate the transmitted signal and the received signal. The inventive transponder can also be used as a transducer. Also, by using an interrogation device that uses two receive antennas, it is possible to locate the position of several transducers with a single interrogation device.

### CROSS-REFERENCE TO RELATED APPLICATIONS

The present application is based on International Application No. PCT/EP2005/056779, filed on Dec. 14, 2005, which in turn corresponds to French Application No. 04 13336 filed on Dec. 15, 2004 and priority is hereby claimed under 35 USC § 119 based on these applications. Each of these applications are hereby incorporated by reference in their entirety into the present application.

### FIELD OF THE INVENTION

The field of the invention is that of surface acoustic wave transponders and associated devices. This invention applies more particularly to the techniques of identifying and locating transponders. It also applies to the transmission of information or measurements, the transponder then being used as a transducer.

This type of transponder can, in particular, be used on vehicles, and in particular on road vehicles.

### BACKGROUND OF THE INVENTION

The surface acoustic wave (SAW) devices are used to produce remote interrogation systems and are like small radar systems.

They generally comprise:
An interrogation system comprising means of transmitting/receiving radiofrequency waves associated with data processing electronics; and
At least one surface acoustic wave SAW transponder.

The operating principle is as follows:
the interrogation system sends an interrogation signal to the SAW transponder;
the SAW transponder captures the interrogation signal, combines it with its own impulse response and retransmits a duly processed echo to the interrogation system;
the receiver of the interrogation system detects, outside the transmission time band of the interrogation signal, all or part of the echo from the SAW transponder and extracts from the response received the information encoded by the transponder which is then processed by the processing electronics.

There are two major families of SAW transponders:
delay line transponders;
resonator transponders.

An SAW device comprising a delay line transponder normally comprises, as indicated in FIG. 1:
an interrogation system 2;
at least one transponder 1 comprising:
   an antenna 100;
   an interdigital electrode comb transducer 11 and a delay line 12 connected to the antenna 100.

The interrogation system 2 sends a radiofrequency pulse 21 of low time width. The antenna 100 of the transponder 1 captures the radiofrequency signal. The transponder 1 comprises a transducer 11 which converts the radiofrequency signal 21 into an acoustic pulse 22. One or more acoustic reflectors 12 reflect the pulse 22 as a plurality of echos 23. The transducer 11 converts this series of acoustic echos into a radiofrequency pulse 24 retransmitted by the antenna 100. This pulse 24 is therefore a succession of replicas of the interrogation signal and constitutes the transponder's identification code.

This system has the following drawbacks:
the interrogation signal 21 must be of a duration that is shorter than the individual delay τ entered on the SAW transponder 1 in order to be able to separate the various retransmitted echos 23 in time. This condition determines:
   either the minimum bandwidth B of the system. B must be greater than 1/τ;
   or the individual delay τ with given band B. τ must be greater than 1/B. In a system with narrow band B, the delay τ is, consequently, great and leads to SAW devices that are of large size and therefore costly;
the system allows for the simple identification of only one transponder at a time. To differentiate several transponders, it is necessary:
   to encode the position of the reflectors so as to obtain delays τ that are variable from one device to another; or
   to increase the number of reflectors, which leads either to an increase in the length of the transponder or to a greater complexity of the processing system in order to extract the relevant information.

An SAW device comprising one or more resonator transponders normally comprises, as indicated in FIG. 2:
an interrogation system 2;
at least one transponder 1 comprising:
   an antenna 100;
   an interdigital electrode comb transducer 11 and an SAW resonator cavity 13 characterized by its central frequency F and its quality factor Q. The cavity 13 comprises two series of reflectors evenly spaced at a distance d. The transducer is connected to the antenna 100.

The interrogator 2 sends a long radiofrequency pulse to charge the transponder 1. When the transmission stops, the transponder is discharged to its natural resonance frequency with a time constant τ equal to Q/πF. This discharge of the transponder constitutes the return echo detected by the interrogator's receiver. A spectral analysis can then be used to get back to the frequency of the transponder which constitutes its identification. This analysis can be performed by algorithms based on Fourier transformation, for example of Fast Fourier Transform (FFT) type.

This system has the following drawbacks:
the received signal is transient when the transponder is discharged, so the sensitivity of the system is weak;
processing by spectral analysis is complex.

Also, these systems do not make it possible to locate one transponder among others with a single interrogation system. Consequently, each transponder has an associated interrogation system. This principle is costly and can prove complex to implement, either because of size problems, or because of transmit and receive signal management problems.

The transponder and the associated remote interrogation system according to the invention make it possible to resolve these various drawbacks. The transponder comprises a surface acoustic wave device, comprising an electronic filter with narrow spectral band centered on a central frequency and a delay line operating in reflection mode. By having narrowband filters centered on different frequencies, it is thus possible to easily discriminate between different transponders. The delay lines make it possible to offset the transmitted signal in time from the received signal. The inventive transponder can also be used as a transducer. Also, by using an interrogation device that uses two receive antennas, it is possible to locate the position of several transducers with a single interrogation device.

More specifically, the subject of the invention is an electronic transponder comprising at least one antenna for receiving and transmitting radiofrequency signals and at least one surface acoustic wave device, characterized in that said device comprises at least one electronic filter with narrow spectral band centered on a central frequency and a delay line operating in reflection mode, the electronic filter and the delay line being arranged in series.

Advantageously, the device comprises a number of electronic filters with narrow spectral band, each spectral band of each filter being centered on a different central frequency, said electronic filters being associated in parallel and the delay line being arranged in series with the association of said filters.

Advantageously, the transponder comprises means of transducing a physical quantity by varying one or more of the central frequencies or means of modulating the received radiofrequency signal, one of said modulation means possibly being an on/off switch. In a particular embodiment, the transponder comprises at least three filters, the first intended to measure pressure and the second and third intended to measure temperature.

Another subject of the invention is an electronic remote interrogation device comprising at least one first electronic assembly for generating radiofrequency signals, a second electronic assembly for processing radiofrequency signals and at least one transponder, comprising one of the above characteristics.

Advantageously, the first electronic assembly for generating signals comprises at least electronic frequency synthesis means making it possible to generate a signal at a variable transmission frequency located in the spectral band of the transponder and electronic means making it possible to transmit an amplitude-modulated radiofrequency signal, the amplitude modulation being at a variable transmission frequency located in the spectral band of the transponder. The duration of the transmission signal can be substantially greater than the ratio of the overvoltage coefficient of the electronic filter of the transponder to its central frequency.

Advantageously, the first electronic assembly for generating radiofrequency signals and the second electronic assembly for processing radiofrequency signals have a common antenna, called transmit/receive antenna, and electronic control means making it possible to guide the transmission signal from the first electronic transmission assembly to said antenna and to guide the reception signal from said antenna to the second electronic receive assembly. Furthermore, the second electronic assembly for processing radiofrequency signals can comprise amplitude demodulation means, sampling means and electronic processing means making it possible at least to determine the amplitude and the frequency of the received signals. The second electronic assembly for processing radiofrequency signals can also comprise at least one analog/digital converter for digitally processing the signal.

Advantageously, when a signaI is transmitted by the first electronic assembly, the sampling of the received signals begins at an instant between the end of the transmission of the transmitted signal and the end of the transmission of said transmitted signal plus the time delay of the delay line of the transponder.

Advantageously, the second electronic assembly for processing radiofrequency signals comprises a second receive antenna remote from the first antenna and electronic means of comparing the phases of the radiofrequency signals received by the first and second antennas. The distance separating the first antenna from the second antenna is less than or equal to half the wavelength corresponding to the central frequency of the transponder.

Advantageously, the method of installing an electronic remote interrogation device comprises the following preliminary installation steps:
Determination of the possible locations of the transponders;
Plotting of the constant phase-shift curves between the two antennas;
Optimization of the location and the orientation of the antennas so that there is a different phase shift between the signals received from a first transponder and from any second transponder;
Storage of said phase shifts in electronic memories associated with the electronic processing means.

Advantageously, the remote interrogation device transmits and receives radiofrequency signals in the 433 megahertz ISM band.

The device is advantageously mounted on a vehicle and in particular a road vehicle.

### BRIEF DESCRIPTION OF THE DRAWINGS

The invention will be better understood and other advantages will become apparent from reading the description that follows given as a nonlimiting example and from the appended figures, in which:

FIG. 1 represents the principle of a first SAW interrogation device according to the prior art;

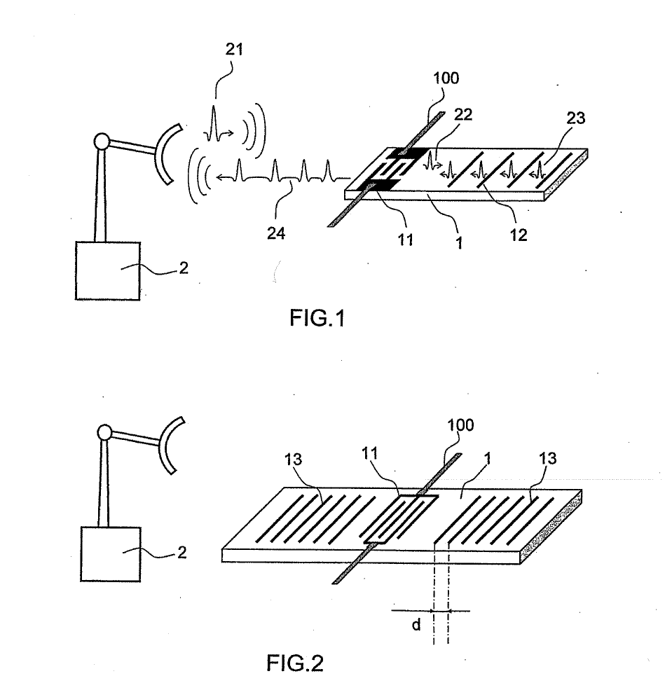

FIG. 2 represents the principle of a second SAW interrogation device according to the prior art;
FIG. 3 represents a transponder according to the invention;

FIG. 4 represents a variant of a transponder according to the invention;

FIG. 5 represents a remote interrogation device according to the invention;

FIGS. 6, 7 and 8 represent the principle of locating a plurality of transponders according to the invention;

FIG. 9 represents a second remote interrogation device comprising two antennas according to the invention.

### DESCRIPTION OF THE PREFERRED EMBODIMENTS

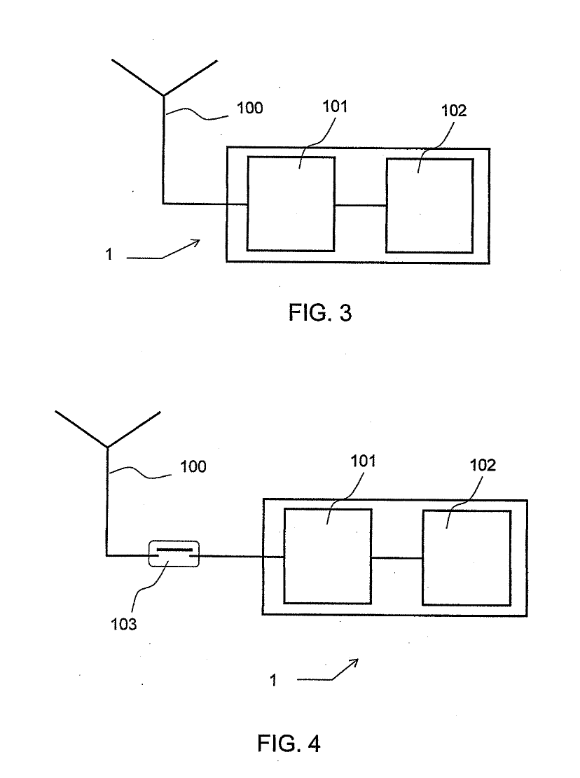

FIG. 3 represents a transponder 1 according to the invention. It comprises an antenna 100 linked to a dipole-type SAW device, itself comprising a cascaded narrow-band filter 101 and delay line 102 with total reflection.

In the case where the transponders 1 have only one single narrow-band filter, it is entirely defined by its reflection-mode transfer function. Its main characteristics are:
the central frequency F which is the parameter identifying the transponder;
the bandwidth B which is F/Q, Q being the quality factor of the resonator;
the attenuated band of width 2Δf, Δf being the minimum difference making it possible to unambiguously differentiate two frequencies F₁ and F₂ corresponding to two different transponders;
the transit time τ of the reflection-mode delay line.

Advantageously, the transponder can comprise a number of electronic filters with narrow spectral band, each spectral band of each filter being centered on a different central frequency, said electronic filters being associated in parallel and the delay line being arranged in series with the association of said filters. It is thus possible to produce more complex functions on a single transponder.

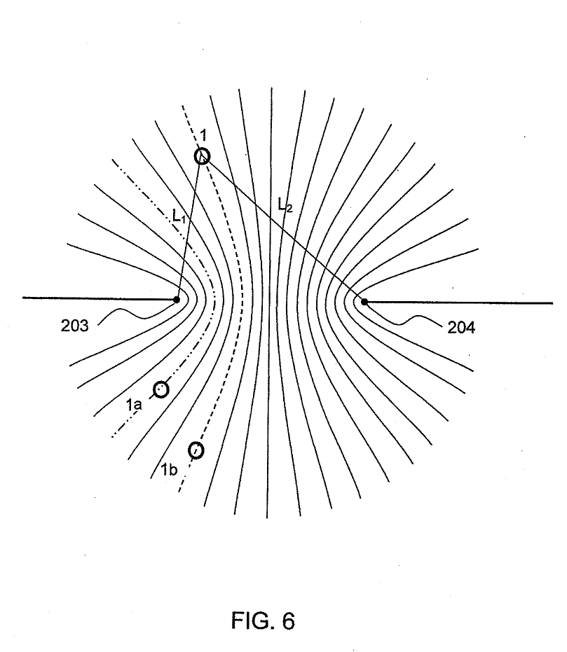

As illustrated in FIG. 5, an electronic remote interrogation device comprises at least:
a first electronic assembly for generating radiofrequency signals 210;
a second electronic assembly for processing radiofrequency signals 220;
an assembly 200 for transmitting/receiving radiofrequency signals comprising a common antenna 201, called transmit/receive antenna, and electronic control means 202;
and at least one transponder 1.

The first electronic assembly for generating signals 210 comprises electronic frequency synthesis means 211 and electronic amplification means 212.

The electronic means 211 make it possible to generate a signal at a variable transmission frequency located in the spectral band of the transponder. The frequency synthesis covers the frequency band of the target application with a step that is as fine as half the bandwidth of the SAW transponders. The frequency is fixed on each transmission and can vary from one transmission to the next.

The radiofrequency signal generated can be amplitude modulated, the amplitude modulation being at a variable transmission frequency located in the spectral band of the transponder. As an example, the temporal formatting of the transmission signal can be a 100% amplitude-modulated carrier of “OOK” (On-Off Keying) type.

The duration T of the transmitted pulse is long enough to allow the response from the filter of the SAW transponder to reach its standing state at the end of transmission. Thus, at the end of interrogation, the response from the transponder is equal to its harmonic response. Consequently, the duration T is substantially greater than the ratio of the overvoltage coefficient Q of the electronic filter of the transponder to its central frequency F. In practice, the duration T is chosen such that T is greater than 3Q/πF. For example, for a frequency of 433 megahertz, taken from the ISM (Industrial, Scientific, Medical) band, and for an overvoltage coefficient Q of 5000, the duration T should be greater than 11 microseconds.

The first electronic assembly for generating radiofrequency signals 210 and the second electronic assembly for receiving radiofrequency signals 220 have a common antenna 201, called transmit/receive antenna, and electronic control means 202 making it possible to guide the signal from the first electronic assembly for generating signals to said antenna 201 and to guide the reception signal from said antenna to the second electronic receiving and processing assembly 220. The control is symbolized in FIG. 5 by a semi-circular arrow.

The second electronic assembly for receiving radiofrequency signals 220 comprises means of amplifying and detecting the amplitude of the received signal 221, sampling means 222 and electronic processing means 224 making it possible to determine the amplitude and the frequency of the received signals. The second electronic assembly 220 for receiving radiofrequency signals can also comprise at least one analog/digital converter 223 for digitally processing the signal. In this case, the data processing is carried out digitally.

This second assembly must be operational from the end of the transmission phase. The sampling of the demodulated signal thus begins after the end of the transmission at an instant between T and T+τ. The amplitude demodulation of the received signal can be coherent or incoherent depending on the application considered.

If a single transponder 1 is in the field of the antenna 201, the signals obtained coming from the transponder are a relative measure of the amplitude of the transfer function of the transponder's filter at the frequency concerned. By varying the interrogation frequency, it is possible to describe this transfer function and extract from it the central frequency of the transponder and therefore identify it.

If a plurality N of different transponders of different central frequency F are in the interrogation field of the antenna, the signals obtained are the relative sum of the amplitudes of the different transfer functions of the transponders' filters at the frequency concerned. By varying the interrogation frequency, it is possible to describe all the superimposed transfer functions and extract from them the central frequencies of the transponders detected and therefore identify them.

In order for the N transponders to be able to operate together without interfering with each other, the following conditions must be satisfied:
the frequency band allocated to the application is divided into N separate subbands of comparable width, each subband being assigned to a given transponder;
the central frequency of the transponder must remain within this subband for the identification to be made unambiguously;
the transfer function of a given transponder must exhibit a sufficient attenuation in the other subbands for the same reason;
the delay τ depends on the electronics of the interrogation system; its role is to delay the signal retransmitted by the transponder so that the receiver can process the end of said signal outside the time band of the transmission signal and the echos reflected by the system's environment.

The transient signals linked to the switching-off of the interrogation signal at the time T return to the receiver after a time greater than T+τ and therefore do not disturb the measurement performed between T and T+τ.

As an example, and with the same numerical values as previously, a subband of 200 kilohertz is sufficient for each transponder and a delay τ of 2 microseconds is sufficient to separate the transmitted signal from the received signal.

The device as a whole uses standard electronic components both for transmission and for reception.

As has been seen, the basic function of the interrogation system is to measure the central frequency of the transponders. For the identification function, a low-resolution measurement is sufficient to discriminate the N possible frequency subbands of the N transponders. The system can also comprise analysis means capable of a high-resolution measurement with a finer frequency analysis step and/or an interpolation between measurements obtained with a rougher analysis step. This fine measurement makes it possible to use the SAW transponder as a transducer of a quantity which directly affects its central frequency such as, for example, temperature, pressure or stress.

The transducer or sensor function is therefore a functionality inherent to the inventive system. Implementing it requires only software additions to the interrogation and extraction sequences for the digital information obtained from the processing means.

Obviously, it is possible for the device to comprise a number of narrow spectral band electronic filters, each spectral band of each filter being centered on a different central frequency, said electronic filters being associated in parallel and the delay line being arranged in series with the association of said filters. For example, the transponder can comprise at least three filters, the first intended to measure pressure and the second and third intended to measure temperature.

By adding external modulation systems controlled by sensors of physical quantity to the passive SAW transponder, it is possible to convert it into an extrinsic sensor and thus increase the functionalities of the interrogation system.

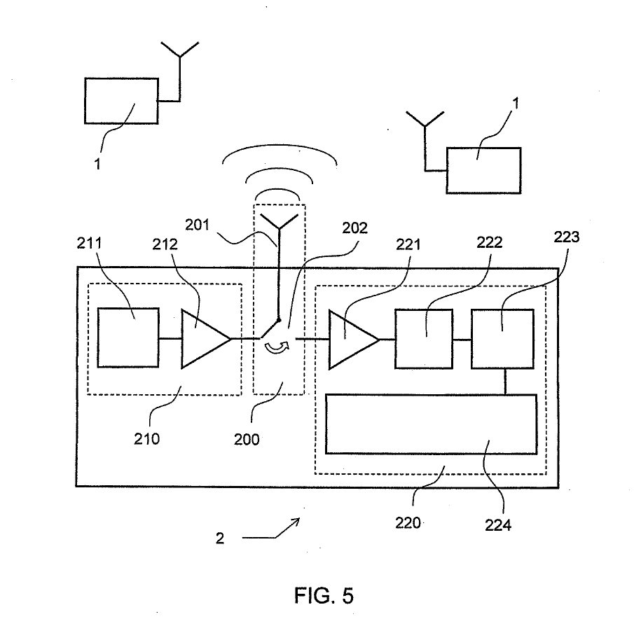

FIG. 4 illustrates this principle. A radiofrequency switch 103 is incorporated between the antenna and the SAW device. It is then possible to modulate the amplitude of the signal received and retransmitted by the transponder by on/off keying. The interrogation system, after an identification sequence in which the switch is necessarily on, can interpret any subsequent variation of the received level as information transmitted by the transponder concerning a given state thereof. The passive nature of the transponder is retained if the switch is itself also passive. The switch is, for example, a pushbutton, a micro-mechanical system, a Reed-relay type relay. It is then actuated by a non-electrical energy source for its change of state which can be obtained by a mechanical displacement, a convergence of a magnetic source or a pressure or temperature variation.

An active electronic switch can also be used if an electrical energy source is available on the transponder such as a cell battery or a remote power feed.

The inventive devices also make it possible to implement an additional functionality: the locating of the passive SAW transponders when said transponders are expected to be in predetermined locations but arranged randomly with respect to the identifier. For example, in a motor vehicle, it is thus possible to find the position of a given seat or a given wheel after a dismantling-reassembly operation.

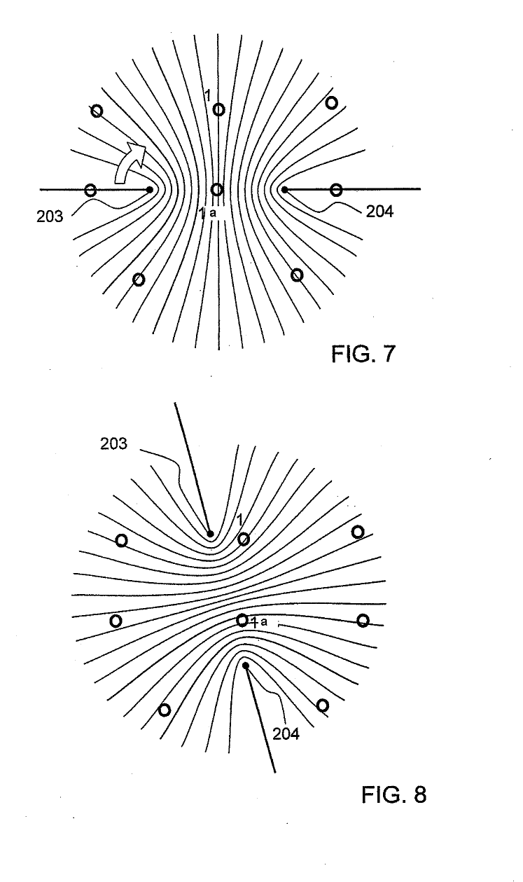

The locating principle is indicated in FIG. 6. It is based on measuring the difference in direct paths L₁ and L₂ between a transponder 1 and two receive antennas 203 and 204. If the antennas are separated by a distance a, the difference varies between 0 and a and the points of similar difference or iso-difference describe families of hyperboloids, the focal points of which are the antennas. In FIG. 6, these families of hyperboloids are represented in a cutting plane passing through the two antennas 203 and 204 and are, in this case, hyperbolas.

For the system to operate correctly, it is essential for a measured path difference to be attributable only to a single predetermined location for a transponder. For example, in FIG. 6, the transponders 1 and 1a are on the same hyperbola arc represented by a dotted line and, consequently, it is not possible to discriminate them by a measurement of the path variation. In contrast, the transponders 1 and 1b are located on two different hyperbola arcs represented by two different dotted lines and, consequently, it is possible to discriminate them by a measurement of the path variation. In the case where the number of transponders is low, it is still possible to find an appropriate positioning of the two receive antennas relative to the locations of the transponders as indicated in FIGS. 7 and 8. In these figures, eight transponders are located in one and the same plane. In FIG. 7, the transponders 1 and 1a cannot be discriminated because they are located in the same hyperbola arc. A change of orientation of the antennas 203 and 204 indicated by a semi-circular arrow in FIG. 7 then makes it possible to discriminate all the transponders as indicated in FIG. 8.

Functionally, the measurement of the electrical path difference is done by measuring the differential delay between the two signals obtained from one and the same transponder and captured by each of the two receive antennas. By using the same interrogation signal as for the identification of the transponder and by identically measuring the samples between T and T+τ, measuring the differential delay amounts to measuring the differential phase between the two signals, these samples being representative of the harmonic response of the transponder. This measurement can be performed by measuring the sine representative of the phase difference between the two signals. To eliminate any ambiguity concerning the determining of the electrical path difference by measuring a phase, necessarily known to within a phase shift of π, the path difference must be less than a half wavelength of the interrogation signal. This condition is satisfied if the difference between the receive antennas is less than this value. For example, at the frequency of 433 megahertz, the distance separating the antennas must remain less than 0.35 meters.

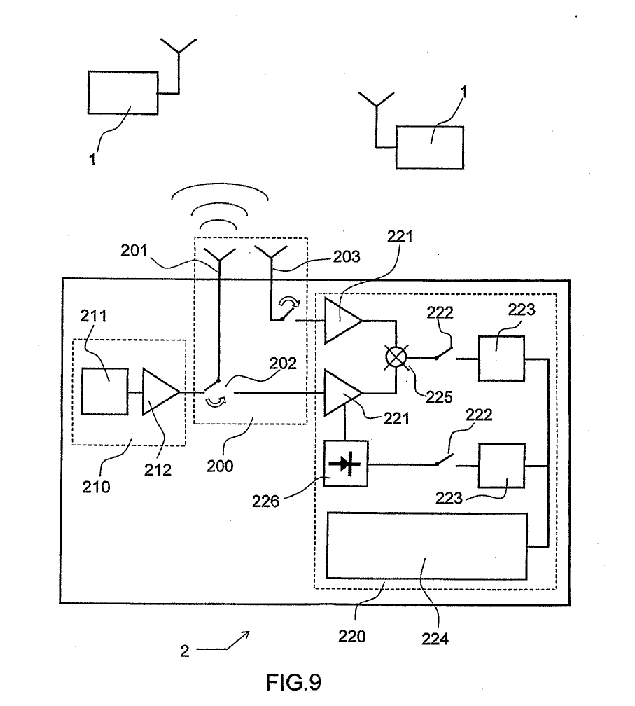

To handle the locating function, the interrogation system comprising a first electronic assembly for generating radiofrequency signals 210 and a second electronic assembly for processing radiofrequency signals 220 requires an additional reception channel as indicated in FIG. 9, the first electronic assembly for generating radiofrequency signals 210 comprising the electronic frequency synthesis means 211 and the electronic amplification means 212 being retained.

This reception channel comprises a separate antenna 203 and the electronic means needed to measure the differential phase between the echo received by this second antenna 203 and the echo received by the first antenna 201. For the phase differential measurement, different electronic architectures are possible. As an example, FIG. 9 shows an exemplary electronic architecture. It comprises:
means 221 and 226 making it possible to detect the amplitude of the echo received by the antenna 201. Thus, the signal is identified;
said means 221 making it possible to limit the amplitude and directly demodulating the phase of the two echos received by the two antennas 201 and 203;
means 225 of mixing the radiofrequency signals duly limited by the devices 221;
two sample and hold devices 222 handling the sampling at the output of the phase demodulator 225 and of the amplitude detector 226. The sampling is performed between the instants T and T+τ;
analog/digital conversion means 223 making it possible to convert analog signals into digital signals;
digital processing means 224 for digitally processing the signal.

It is also possible to use appropriate electronics to implement the phase and quadrature demodulation of the signals received, the sampling of said signals between T and T+τ, their conversion into digital signals and amplitude and phase measurement on the digitized samples by implementing a conversion of Cartesian coordinates into polar coordinates.

The method of installing an electronic remote interrogation device of this type comprising at least two transponders comprises the following preliminary installation steps:
Determination of the possible locations of the transponders;
Plotting of the constant phase-shift curves between the two antennas;
Optimization of the location and the orientation of the antennas so that there is a different phase shift between the signals received from a first transponder and from any second transponder;
Storage of said phase shifts in electronic memories associated with the electronic processing means 224.

In an operational situation, the interrogation system compares the measured phase with the stored phase values to decide on the location of an identified transponder.

A preferred frequency band for this type of system is the ISM (Industrial, Scientific, Medical) band, having a frequency of 433 megahertz for its central frequency and a bandwidth of 1.7 megahertz.

One major field of application is the identifying and locating by a wireless system of seats within a vehicle comprising up to eight seats depending on the configuration of the vehicle, the seats of the rear rows being standardized and interchangeable. The transponders are interrogated in the ISM band. By way of examples, the transponders provide information on the presence or absence of a seat, mainly at the rear of the vehicle, the locations of the seats that are present, the occupancy or otherwise of a seat, the fastening or non-fastening of a seat belt or the temperature of the seat.

1. An electronic transponder comprising:
an one antenna for receiving and transmitting radiofrequency signals; an
surface acoustic wave device, wherein an
electronic filter with narrow spectral band centered on a central frequency and a delay line operating in reflection mode, the electronic filter and the delay line being arranged in series.

2. The electronic transponder as claimed in claim 1, wherein comprising a number of electronic filters with narrow spectral band, each spectral band of each filter being centered on a different central frequency, said electronic filters being associated in parallel and the delay line being arranged in series with the association of said filters.

3. The electronic transponder as claimed in claim 1, wherein the transponder comprises means of transducing at least one physical quantity by varying at least one central frequency.

4. The electronic transponder as claimed in claim 3, wherein the transponder comprises at least three filters, the first intended to measure pressure and the second and third intended to measure temperature.

5. The electronic transponder as claimed in claim 1, wherein the transponder comprises means of modulating the received radiofrequency signal.

6. The electronic transponder as claimed in claim 5, wherein the modulation means are an on/off switch.

7. An electronic remote interrogation device Comprising:
at least one first electronic assembly for generating radiofrequency signals, a second electronic assembly for processing radiofrequency signals and at least one transponder, wherein said transponder is as claimed in claim 1.

8. The electronic remote interrogation device as claimed in claim 7, wherein the first electronic assembly for generating signals comprises at least electronic frequency synthesis means making it possible to generate a signal at a variable transmission frequency located in the spectral band of the transponder.

9. The electronic remote interrogation device as claimed in claim 8, wherein the first electronic assembly for generating signals also comprises electronic means making it possible to transmit an amplitude-modulated radiofrequency signal, the amplitude modulation being at a variable transmission frequency located in the spectral band of the transponder.

10. The electronic remote interrogation device as claimed in claim 9, wherein the duration (T) of the transmission signal is substantially greater than the ratio of the overvoltage coefficient (Q) of the electronic filter of the transponder to its central frequency (F).

11. The electronic remote interrogation device as claimed in one of claim 7, wherein the first electronic assembly for generating radiofrequency signals and the second electronic assembly for processing radiofrequency signals have a common antenna, called transmit/receive antenna and electronic control means making it possible to guide the transmission signal from the first electronic generation assembly to said antenna and to guide the reception signal from said antenna to the second electronic processing assembly.

12. The electronic remote interrogation device as claimed in one of claim 7, wherein the second electronic assembly for processing radiofrequency signals comprises amplitude demodulation means, sampling means and electronic processing means making it possible at least to determine the amplitude and the frequency of the received signals.

13. The electronic remote interrogation device as claimed in claim 12, wherein the second electronic assembly for processing radiofrequency signals also comprises at least one analog/digital converter for digitally processing the signal.

14. The electronic remote interrogation device as claimed in claim 7, wherein, when a signal is transmitted by the first electronic assembly, the sampling of the received signals begins at an instant between the end of the transmission of the transmitted signal and the end of the transmission of said transmitted signal plus the time delay of the delay line of the transponder.

15. The electronic remote interrogation device as claimed in claim 7, wherein the second electronic assembly for processing radiofrequency signals comprises a second receive antenna remote from the first antenna and electronic means of comparing the phases of the radiofrequency signals received by the first and second antennas.

16. The electronic remote interrogation device as claimed in claim 15, the distance (a) separating the first antenna from the second antenna is less than or equal to half the wavelength corresponding to the central frequency (F) of the transponder.

17. A method of installing an electronic remote interrogation device as claimed in claim 15, having at least two transponders, it comprises the following preliminary installation steps:
determination of the possible locations of the transponders;
plotting of the constant phase-shift curves between the two antennas;
optimization of the location and the orientation of the antennas so that there is a different phase shift between the signals received from a first transponder and from any second transponder; and
storage of said phase shifts in electronic memories associated with the electronic processing means.

18. The remote interrogation device as claimed in claim 7, wherein said device transmits and receives radiofrequency signals in the 433 megahertz ISM band.

19. A vehicle, characterized in that it comprises at least one electronic remote interrogation device as claimed in claim 7.

20. The electronic remote interrogation device as claimed in claim 8, wherein the first electronic assembly for generating radiofrequency signals and the second electronic assembly for processing radiofrequency signals have a common antenna, called transmit/receive antenna and electronic control means making it possible to guide the transmission signal from the first electronic generation assembly to said antenna and to guide the reception signal from said antenna to the second electronic processing assembly.
